(19) United States
(12) Patent Application Publication
(10) Pub. No.: US 2026/0104572 A1
(43) Pub. Date: Apr. 16, 2026

(54) SUBSTRATE FOR PRODUCING AN OPTICAL ELEMENT, OPTICAL ELEMENT AND ALSO SEMICONDUCTOR TECHNOLOGY APPARATUS

(71) Applicant: Carl Zeiss SMT GmbH, Oberkochen (DE)

(72) Inventors: Caren MOELLER, Oberkochen (DE); Sebastian FAAS, Oberkochen (DE); Martin TIMM, Oberkochen (DE); Samer SULEIMAN, Oberkochen (DE); Erik LOOPSTRA, Oberkochen (DE); Joachim RUCK, Oberkochen (DE); Andreas SEIFERT, Oberkochen (DE)

(21) Appl. No.: 19/419,852

(22) Filed: Dec. 15, 2025

Related U.S. Application Data
(63) Continuation of application No. PCT/EP2024/065181, filed on Jun. 3, 2024.

(30) Foreign Application Priority Data
Jun. 14, 2023 (DE) 10 2023 205 565.1

(51) Int. Cl. G02B 7/18; G01N 21/95; G01N 21/956; G02B 5/08; G03F 1/22; G03F 7/00

(52) U.S. Cl. CPC G02B 7/1815; G01N 21/9501; G01N 21/956; G02B 5/0891; G03F 1/22; G03F 7/70233; G03F 7/70316; G03F 7/70891; G03F 7/70958; G01N 2021/95676

(57) ABSTRACT

A substrate for producing an optical element and an optical element are specified. Furthermore, a semiconductor technology apparatus is specified.

### CROSS REFERENCE TO RELATED APPLICATIONS

This is a Continuation of International Application PCT/EP2024/065181, which has an international filing date of Jun. 3, 2024, and which claims the priority of German Patent Application 10 2023 205 565.1, filed Jun. 14, 2023. The disclosures of both applications are incorporated in their respective entireties into the present Continuation by reference.

### FIELD

The techniques disclosed herein relate to a substrate for producing an optical element, in particular for producing a mirror for an EUV projection exposure apparatus, wherein the substrate has temperature-regulating hollow structures, and also relates to an optical element, in particular a mirror for an EUV projection exposure apparatus with a substrate, as well as to a semiconductor technology apparatus.

### BACKGROUND

The following description of the disclosed techniques is given on the basis of an optical element in the form of a mirror and the use thereof in an EUV projection exposure apparatus, wherein heat is dissipated from the mirror by a temperature-regulating fluid in the form of a cooling fluid being made to flow through the temperature-regulating hollow structures present in it.

In principle, however, the following explanations apply generally to optical elements which can be assigned a substrate composed of a substrate material in which temperature-regulating hollow structures are incorporated, through which a temperature-regulating fluid can be made to flow for temperature compensation during operation of the optical element.

In particular, optical elements are used in semiconductor technology apparatuses in which an object is irradiated with a working radiation with the aid of one or more optical elements. Besides an EUV projection exposure apparatus, such semiconductor technology apparatuses include, in particular, mask inspection apparatuses and wafer inspection apparatuses.

On the one hand, temperature regulation may be cooling or heating of the optical element or of at least one area of the optical element. That is to say that, with the aid of the temperature-regulating fluid, the optical element as a whole or at least in a volume area is brought to a temperature which it was not at previously.

On the other hand, however, temperature regulation may also have the effect that a specific temperature or a specific temperature range of the optical element or of at least one area of the optical element is or stays maintained.

These considerations furthermore apply generally to components with a corresponding substrate which carries or can carry one or more functional units and incorporated in which are temperature-regulating hollow structures through which a temperature-regulating fluid can be made to flow for temperature regulation during operation of the component. Such a component may provide, for example, a sensor device; in this case, the substrate carries sensor units as functional units.

Microlithographic projection exposure apparatuses are used in chip production in order to transfer structures on a mask to a photoresist that has previously been applied to a wafer. For this purpose, the mask is illuminated with light and imaged onto the light-sensitive layer in a reduced size. In EUV projection exposure apparatuses, the light has a wavelength of between approximately 5 nm and approximately 30 nm; the commercially available apparatuses use light with a wavelength of 13.5 nm.

However, there are no optical materials that have a sufficiently high transmissivity for such short wavelengths. Therefore, in EUV projection exposure apparatuses, the lens elements that have been customary at longer wavelengths are replaced by mirrors and for this reason the mask also contains a pattern of reflective structures.

The provision of mirrors for EUV projection exposure apparatuses is technologically demanding. The substrate consists of a substrate material, which is generally glass, for example quartz glass, titanium-doped quartz glass such as ULE®, or a glass ceramic. Suitable glass ceramics are offered under the trade names Clearceram® or Zerodur® and have the property of having a very low coefficient of thermal expansion at the operating temperature of the mirror.

A coating which reflects the EUV light and consists of a multiplicity of thin double layers with alternating refractive indices is applied to the substrate.

Even with such complexly constructed coatings, however, the reflectivity of the mirrors for the EUV light is rarely more than 70%, and even this is only for light which impinges on the reflective coating with normal incidence or with angles of incidence of a few degrees. The portion of the EUV light which is not reflected by the coating is absorbed in the substrate, where it leads to considerable heating since the EUV light sources used are very powerful. Even if glass ceramics with low coefficients of thermal expansion are used, the heating may lead to unacceptable changes in shape of the mirrors.

It has therefore been proposed to provide the substrates with temperature-regulating hollow structures, which in this case are cooling hollow structures, wherein in particular temperature-regulating channels in the form of cooling channels are provided, through which water or some other temperature-regulating fluid, i.e., here a cooling fluid, flows during operation and dissipates heat in this way. Such temperature-regulating channels may have small cross-sectional diameters of the order of magnitude of only about 1 mm2 and ideally run just below the reflective coating.

An overview of the hitherto known methods for creating temperature-regulating channels is contained in the application DE 10 2021 214 310.5, the disclosure of which is hereby incorporated in its entirety. Particularly promising are methods in which an ablation light beam is successively focused on ablation locations at which temperature-regulating channels are intended to be produced and the substrate material is removed by the ablation light beam.

In the case of this method, modified substrate material, which has a higher susceptibility to a chemically active treatment medium relative to unprocessed substrate material, is produced adjoining the ablation locations, i.e., adjacent to and not at the focal points of the light beam. In particular, there is a higher susceptibility to etching. The modified substrate material forms the intermediate layer mentioned at the beginning and the material-free areas created by ablation form the intermediate hollow structure mentioned at the beginning, so that a corresponding intermediate structure is formed.

In the case of this method, the modified substrate material is produced in particular by absorption of the high-energy ablation light beam and by thermal diffusion from the ablation locations of the process heat produced, though before processing of the substrate there are no defined indications as to the extent to which the modified material will be produced. In the case of a laser, specialists refer to an area with modified substrate material as a so-called laser affected zone, or LAZ for short. The modified substrate material may also differ relative to the substrate material of the substrate inter alia in terms of density, coefficient of thermal expansion and the material stresses present.

However, such a materially inhomogeneous substrate is not suitable for use in an EUV projection exposure apparatus. Therefore, the modified substrate material must be removed; in the case of the known method, the modified substrate material is etched away in a downstream process step with the aid of an etching agent, such as in particular hydrofluoric acid HF or potassium hydroxide KOH; the desired temperature-regulating hollow structure is then formed. This means that as a result the modified substrate material defines the cross sections in the course of the temperature-regulating hollow structure to be created.

The overall process speed for the formation of the desired temperature-regulating hollow structure is limited particularly by the rate of removal; the substrate material is removed over almost the entire cross section of the desired temperature-regulating hollow structure and the modified substrate material is generally only produced with a small layer thickness. In addition, fluctuations in the microstructure of the substrate material due, for example, to areas with different refractive indices/different transmission or due to the formation of thermal lenses, can cause fluctuations in the material removal, which in turn can lead to undesirable deviations in the cross-sectional course of the temperature-regulating hollow structures and roughness on their lateral surfaces.

### SUMMARY

The object of the techniques disclosed herein is to specify a substrate, an optical element and a semiconductor technology apparatus of the kind mentioned above which take these thoughts into account and by which, in particular, temperature-regulating hollow structures can be incorporated into the substrate with high precision and quality as well as good process speed, so that, using such an optical element, inter alia structured electronic components with significantly small structures can be produced.

In the case of a substrate of the kind mentioned at the beginning, the object mentioned above is achieved in that at least one temperature-regulating hollow structure defines an inner lateral surface which has, at least in some areas, an average roughness Ra in accordance with DIN EN ISO 25178, as of 04/2023, of between 10.0 μm and 5.0 μm, which in particular may lie between 10.0 μm and 6.5 μm, between 10.0 μm and 8.0 μm, between 8.5 μm and 5.0 μm, between 7.0 μm and 5.0 μm or between 8.5 μm and 6.5μm, or which has, at least in some areas, an average roughness Ra of 5.0 μm and less, which in particular lies between 5.0 μm and 0.1 μm, preferably between 4.5 μm and 0.125 μm, between 4.0 μm and 0.15 μm, between 3.5 μm and 0.175 μm or between 3.0 μm and 0.2 μm,
wherein the temperature-regulating channel (34) has a strongly curved portion (118) which has an angle of curvature of between 60° and 120°, in particular between 80° and 100°, preferably of about 90°.

The object mentioned above is also achieved by a substrate of the kind mentioned at the beginning in which at least one temperature-regulating hollow structure defines an inner lateral surface which has a surface topography of which the geometric shape results from an overlaying, at least in some areas, of sunken structures which extend into a substrate material of the substrate.

Preferably, one or more sunken structures are segments of in themselves point-symmetrical or at least axis-symmetrical bodies.

Advantageously, the surface topography in this case defines mutually adjoining sunken areas between which peripheral regions, in particular linear peripheral regions, run.

One or more sunken areas may be axis-symmetrical or not axis-symmetrical.

It is advantageous if an axis-symmetrical sunken area follows a portion of the outer lateral surface of a segment of a sphere, a segment of an ellipsoid or of a paraboloid.

Advantageously, a temperature-regulating hollow structure is a temperature-regulating channel which has one or more of the following features:
a) the temperature-regulating channel has a diameter of between 0.5 mm and 20 mm, preferably between 1 mm and 5 mm;
b) the temperature-regulating channel has a length of at least 10 cm, at least 15 cm or at least 20 cm.
c) the temperature-regulating channel is curved or has at least one curved portion;
d) the temperature-regulating channel has a portion which follows the curvature of a carrier surface for a coating of the substrate;
e) the temperature-regulating channel has a strongly curved portion which has an angle of curvature of between 60° and 120°, in particular between 80° and 100°, preferably of about 90°, and follows an arc;
f) the temperature-regulating channel has a strongly curved portion which has an angle of curvature of between 60° and 120°, in particular between 80° and 100°, preferably of about 90°, and follows an arc and defines an outer radius of curvature R and a diameter D, wherein a ratio R/D of the radius of curvature R to the diameter D lies between 2 and 6, preferably between 2.5 and 5 and in particular preferably between 2.5 and 3.5;
g) the temperature-regulating channel is at a distance relative to a carrier surface for a coating of the substrate of 1.0 mm to 50.0 mm, of 1.0 mm to 20.0 mm, of 1.0 mm to 10.0 mm or of 1.0 mm to 5.0 mm.

A safe guarantee of good flow properties is also achieved according to the disclosed techniques in the case of a substrate of the kind mentioned at the beginning which defines a carrier surface for a coating in that, with a lifetime of the substrate of up to 10 years, at least up to five years and at least up to two years, the surface figure of the carrier surface changes by less than 100 pm, in particular by less than 50 pm and further in particular by less than 25 pm.

Synergetically advantageously, some or all of the features explained above can also be realized in a substrate in combinations.

Preferably, temperature-regulating hollow structures are incorporated in the substrate according to the method explained above.

In the case of an optical element of the kind mentioned at the beginning, the object specified above is achieved by a substrate with some or all of the features described above.

With a lifetime of the optical element of up to 10 years, at least up to five years and at least up to two years, the surface figure of the optical element advantageously changes by less than 100 pm, in particular by less than 50 pm and further in particular by less than 25 pm.

These properties have particularly advantageous effects in the case of a mirror for an EUV projection exposure apparatus, wherein the substrate has a carrier surface which carries a coating which is designed at least to reflect at least 50% of EUV light impinging with normal or almost normal incidence.

The mentioned properties of the optical element are advantageously combined.

In the case of a semiconductor technology apparatus, the object is achieved by such an optical element.

This is of particular advantage in the case of an EUV projection exposure apparatus.

In the case of a structured electronic device, the above-mentioned object is achieved in that it was produced with the aid of such a semiconductor technology apparatus.

### BRIEF DESCRIPTION OF THE DRAWINGS

Exemplary embodiments of the disclosed techniques are explained in greater detail below on the basis of the drawings. In these drawings:

FIG. 1 schematically shows a section through an optical element in the form of a mirror for an EUV projection exposure apparatus, which mirror has temperature-regulating hollow structures in the form of temperature-regulating channels through which a cooling fluid is made to flow via a cooling system;

FIG. 2 shows a modification-processing system via which, by pursuing a first process route involving successively focusing a modification light beam on modification locations, modified substrate material is produced at the modification locations, wherein material structures of modified substrate material are incorporated into the substrate;

FIG. 3A shows the detail III A according to FIG. 2 on a larger scale, wherein material structures of a first kind, which are cross-sectionally filling, are incorporated;

FIG. 3B shows a section according to the section line III B-III B in FIG. 3A;

FIG. 4 shows the substrate with incorporated material structures of the first kind;

FIGS. 5A and 5B show the details V A and V B in FIG. 4 on a larger scale;

FIG. 6A shows a detail corresponding to the detail according to FIG. 3A, wherein material structures of a second kind, in which a core area of substrate material remains in the cross section, are incorporated;

FIG. 6B shows a section according to the section line VI B-VI B in FIG. 6A;

FIG. 7 shows details corresponding to the details according to FIGS. 5A and 5B with the material structures of the second kind;

FIG. 8 shows an ablation-processing system via which, by successively focusing an ablation light beam on ablation locations in the substrate, material is removed at the ablation locations, wherein intermediate hollow structures in the material structures are created from modified substrate material;

FIG. 9A shows the detail IX A according to FIG. 8 on a larger scale;

FIG. 9B shows a section according to the section line IX B-IX B in FIG. 9A;

FIG. 10 shows the substrate with incorporated intermediate structures;

FIGS. 11A and 11B show the details XI A and XI B in FIG. 10 on a larger scale;

FIG. 12 shows the ablation-processing system from FIG. 8, wherein intermediate hollow structures are created in the substrate material by pursuing a second process route;

FIG. 13A shows the detail XIII A according to FIG. 12 on a larger scale;

FIG. 13B shows a section according to the section line XIII B-XIII B in FIG. 13A;

FIG. 14 shows the substrate with incorporated intermediate hollow structures;

FIGS. 15A and 15B show the details XV A and XV B in FIG. 14 on a larger scale;

FIG. 16 shows a modified modification-processing system according to FIG. 2 with a device for introducing an auxiliary fluid into the intermediate hollow structures;

FIG. 17A shows the detail XVII A in FIG. 16 on a larger scale;

FIG. 17B shows the section according to the section line XVII B-XVII B in FIG. 17A;

FIG. 18 shows an etching-processing system with which an etching medium can be introduced into the intermediate hollow structures of the intermediate structures;

FIGS. 19A and 19B show the details XIX A and XIX B in FIG. 18 on a larger scale;

FIGS. 20A and 20B show details corresponding to FIGS. 19A and 19B after the etching operation has been completed;

FIGS. 21A, 21B, 21C and 21D shows illustrations of the possibility of correcting irregularities in the intermediate hollow structures;

FIG. 22 shows a substrate for an EUV mirror into which temperature-regulating hollow structures have been incorporated by pursuing the first or second process route;

FIG. 23A shows a topography image of a surface area of a temperature-regulating hollow structure;

FIG. 23B shows a section to illustrate an achieved average roughness Ra;

FIG. 24 schematically shows a longitudinal section of a temperature-regulating hollow structure;

FIG. 25 shows the detail XXV in FIG. 22 on a larger scale;

FIG. 26A shows an image of the surface figure of a substrate with intermediate structures before an etching process;

FIG. 26B shows an image of the surface figure of this substrate with temperature-regulating hollow structures obtained after an etching process;

FIG. 26C shows a representation of the differences in the images according to FIGS. 26A and 26B;

FIG. 27 schematically shows a semiconductor technology apparatus on the basis of the example of an EUV projection exposure apparatus.

### DETAILED DESCRIPTION

### 1. Set-up Of An Optical Element on the Basis of the Example Of An EUV Mirror

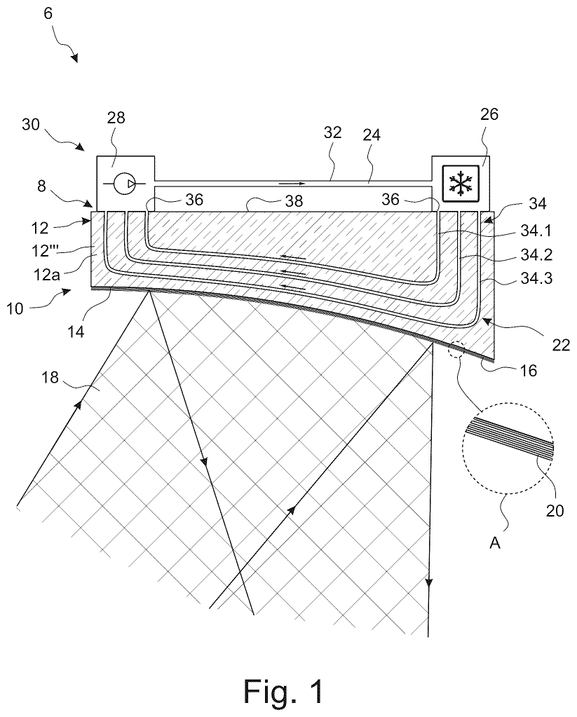

In FIG. 1, a semiconductor technology apparatus explained at the beginning is denoted overarchingly by 6 and a section through an optical element denoted as a whole by 8 is shown, which optical element is illustrated by way of example as a mirror 10 for an EUV projection exposure apparatus. The mirror 10 may be arranged there in the illumination system or in the projection lens.

The optical element 8, and consequently the mirror 10, comprises a substrate 12 composed of a substrate material 12a, which in the case of the present exemplary embodiment of the mirror 10 is therefore a mirror substrate. In practice, such a mirror substrate is in particular a titanium-doped quartz glass.

In the case of the present exemplary embodiment, which is also the preferred embodiment, the substrate 12 is monolithic. In the case of modifications not shown separately, however, the substrate 12 may also be joined together from partial segments. In principle, additive manufacturing methods are suitable in this case. For example, 3D printing methods come into consideration, as do laser welding methods or techniques for the thermal bonding of workpieces.

In the case of the mirror 10, the substrate 12 has a precisely processed surface 14, the curvature of which determines the optical properties of the mirror 10. The surface 14 of the substrate 12 serves as a carrier surface and will also be referred to as such hereinafter. The carrier surface 14 carries a coating 16 which inter alia provides the optical properties of the optical element 8. In the case of the mirror 10 shown here, the coating 16 is designed in such a way that it predominantly reflects incident EUV light 18. As illustrated in the enlarged detail A, in the case of the present exemplary embodiment this coating 16 is of a multilayered form and in particular is constructed from a number of double layers 20 which were applied to the carrier surface 14. The coating 16 has a reflection coefficient of at least 50%, preferably of more than 70%, for normal-incidence EUV light 18. The reflectance achieved during operation depends on the angle of incidence of the EUV light 18.

Besides the double layers 20, the coating 16 may also comprise further layers, which do not contribute to reflection but optionally to stabilization and/or to protection of the coating 16 or the optical element 8 or the mirror 10. For example, protection against components of a hydrogen plasma can thereby be established. Such further layers may be provided between the double layers 20 within the coating 16, between the double layers 20 and the carrier surface 14 and/or on the side of the double layers 20 that is remote from the carrier surface 14.

In the case of an optical element 8, the coating 16 may also be formed by the outer surface of the substrate 12 being modified by processing and/or treatment. In this case, the coating 16 is therefore not a separately applied coating, but rather defines a layer of the substrate 12 as such; the underlying surface as a transition to the substrate material 12a is then the carrier surface 14.

In the case of the mirror 10 explained here and the application of EUV light 18, the unreflected portion enters the substrate 12 and is absorbed there, specifically predominantly in the vicinity of the carrier surface 14. Owing to this absorption, the substrate 12 heats up primarily in the vicinity of the areas of the carrier surface 14 that are exposed to the EUV light 18. Since the coefficient of thermal expansion of the substrate material 12a is not equal to zero and in addition is itself temperature-dependent, the heating up can give rise to changes in shape of the substrate 12 which affect the optical properties of the mirror 10. Relative to optical elements 8, generally speaking, temperature changes in the substrate 12 can affect the optical properties of the optical element 8.

On account of the extremely tight specifications in EUV projection exposure apparatuses, however, changes in the optical properties of the mirrors there are unacceptable or acceptable at most to a negligible extent. However, also generally again, in the case of optical elements 8 the optical properties are intended to remain stable and in the case of components the functionality is intended to be maintained.

In order to minimize temperature fluctuations in the substrate material 12a and associated changes in shape of the substrate 12, a number of temperature-regulating hollow structures 22 are incorporated in the substrate 12.

During the operation of the EUV projection exposure apparatus, a temperature-regulating fluid in the form of a cooling fluid 24 is made to flow through these temperature-regulating hollow structures 22, with cooling water being used in practice; however, other cooling fluids and cooling media are also possible.

The cooling fluid 24 absorbs the quantity of heat input by the EUV light 18 and dissipates it from the substrate 12. For this purpose, the temperature-regulating hollow structures 22 are connected to a cooling unit 26 and a pumping unit 28 of a cooling system, denoted as a whole by 30. The pumping unit 28 sucks up the cooling fluid 24 from the temperature-regulating hollow structures 22 and passes it via a return line 32 to the cooling unit 26. There the cooling fluid 24 is cooled down to its target temperature before it flows once again through the temperature-regulating hollow structures 22. This circuit is illustrated in FIG. 1 by corresponding arrows.

The temperature-regulating hollow structures 22 typically run in the vicinity of the carrier surface 14 and, at least in some areas, parallel thereto.

In the case of the exemplary embodiments described here, the temperature-regulating hollow structures 22 are formed as temperature-regulating channels 34, of which three temperature-regulating channels 34.1, 34.2 and 34.3 are illustrated. The temperature-regulating channels 34 respectively extend between two openings 36, which in FIG. 1 are only denoted in the case of the temperature-regulating channel 34.1, with each temperature-regulating channel 34 being connected via its openings 36 to the cooling unit 26 and to the pumping unit 28. Consequently, depending on assignment, the openings 36 respectively define an inlet or an outlet of the temperature-regulating channels 34 for the cooling fluid 24. The cross section of the temperature-regulating channels 34 do not have to be constant and may be, for example, circular, oval, rectangular or else annular. The temperature-regulating hollow structures 22 may have varying cross sections and shapes depending on the position in the substrate 12. In the case of the present exemplary embodiments, the openings 36 of the temperature-regulating channels 34 are arranged on the rear side 38 of the substrate 12 opposite from the carrier surface 14.

In the case of modifications not shown separately, the temperature-regulating hollow structures 22 may also be more extensive chambers in which the cooling fluid 24 is only slowly exchanged and in which no longitudinal axis, as is characteristic of a channel, is defined.

Also, the arrangement of the temperature-regulating channels 34 shown in the figures is merely given by way of example and may be different in actual systems; the number of temperature-regulating channels 34 may also be greater or smaller. For example, the openings 36 may also be arranged at the lateral flanks of the substrate 12, or at least one temperature-regulating channel 34 which runs meanderingly or spirally through the substrate 12 or a part thereof may have been provided.

In the case of a further modification, it is also possible for one or more temperature-regulating channels 34 to extend from a distribution section or a distribution chamber in the substrate 12; such temperature-regulating channels 34 then open out with their openings 36 at one end or at both ends in such a distribution section or distribution chamber, from which the temperature-regulating channels 34 are then fed with the temperature-regulating fluid. The distribution section or the distribution chamber and optionally that end of a temperature-regulating channel 34 which is remote therefrom are then correspondingly connected to the cooling system 30.

The temperature-regulating channels 34, and in particular the temperature-regulating channel 34.1, is referred to below in the case of all of the exemplary embodiments as representative of generally every kind and arrangement of temperature-regulating hollow structures 22.

During the production of an optical element 8 by applying the methods described here for creating temperature-regulating hollow structures 22, various stages of the substrate 12 are defined.

A first stage of the substrate 12 defines a kind of raw substrate 12′, which is still to a great extent unprocessed and untreated and in the case of which a carrier surface 14 has not yet been structurally formed. In the case of the substrate 12 explained above, which is a mirror substrate, such a raw substrate is, for example, a glass parallelepiped composed of titanium-doped quartz glass.

A second stage of the substrate 12 defines a carrier substrate 12″, in the case of which the carrier surface 14 has been created and formed. This may necessitate a multiplicity of chemical and/or physical working steps, which may comprise operations such as grinding, turning, polishing and/or etching.

A third stage of the substrate 12 then defines an element substrate 12″′, in the case of which the carrier surface 14 is provided at least with the coating 16 determining the optical properties. If the resulting optical element is a mirror, the element substrate 12″′ is consequently terminologically a mirror substrate. Accordingly, the substrate 12 in FIG. 1 also bears the reference sign 12″′, since it is shown there in the stage of the element substrate. If the substrate 12 is, for example, part of a sensor device, as described at the beginning, the element substrate 12″′ is correspondingly terminologically a sensor substrate.

The creation described below of the temperature-regulating hollow structures 22 in the substrate 12 may in principle take place in any stage of the substrate 12. This generally takes place in the stage of the raw substrate 12′, but may also be carried out in, for example, the stage of the carrier substrate 12″ or even in the stage of the element substrate 12″′.

In the present case, the creation of the temperature-regulating hollow structures 22 is explained in particular on the basis of the example of the carrier substrate 12″ in order to illustrate the function envisaged in the case of the present exemplary embodiment for the mirror 10 obtained later.

### 2. Creating the Temperature-Regulating Hollow Structures on the Basis of the Example of the Temperature-Regulating Channels

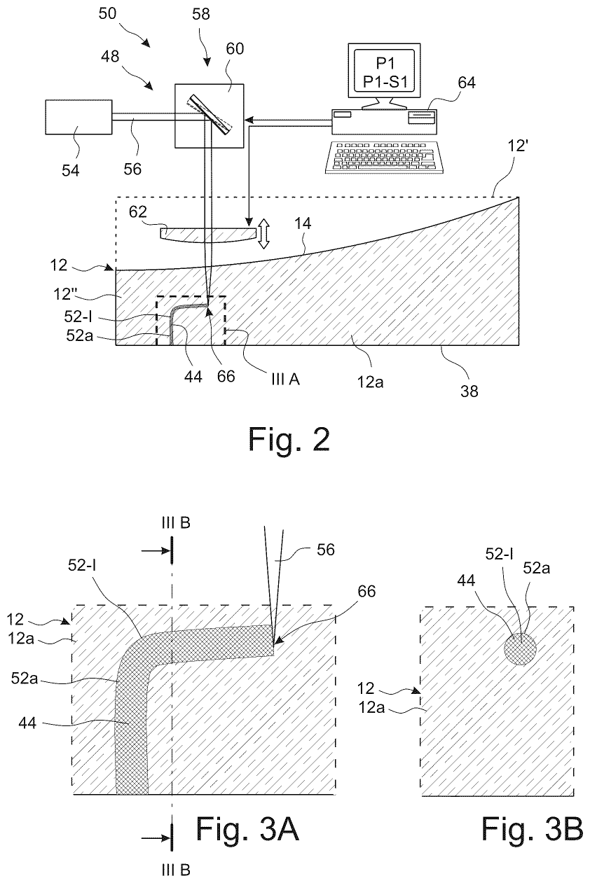

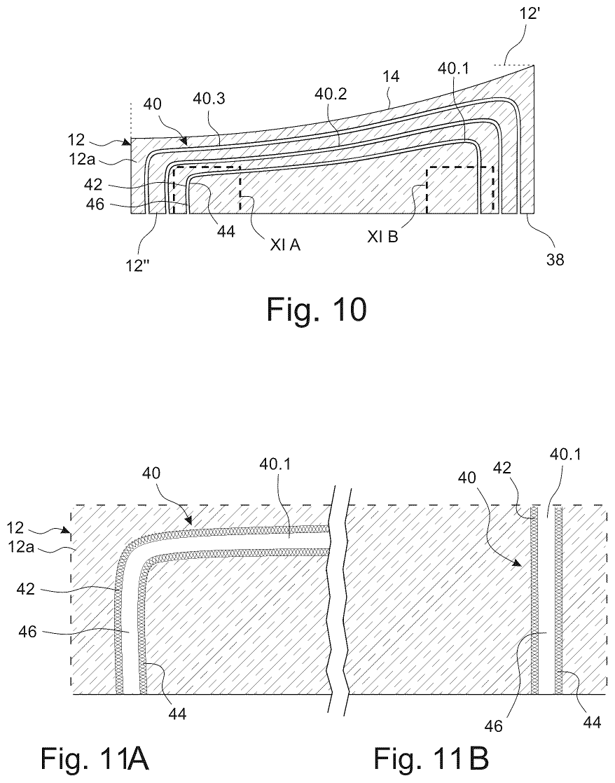

FIGS. 2 to 9B illustrate a first process route P1, with which intermediate structures 40 that can be seen in FIGS. 10, 11A and 11B, which comprise an intermediate layer 42 of modified substrate material 44 and an intermediate hollow structure 46, which is, at least in some areas, bounded by the intermediate layer 42, can be incorporated into the substrate 12.

The modified substrate material 44 has an increased susceptibility to a chemically reactive treatment medium relative to the substrate material 12a and can be removed in a downstream process, whereby the desired temperature-regulating hollow structures 22, i.e., here the temperature-regulating channels 34, are completed starting from the intermediate structures 40; this is discussed further below.

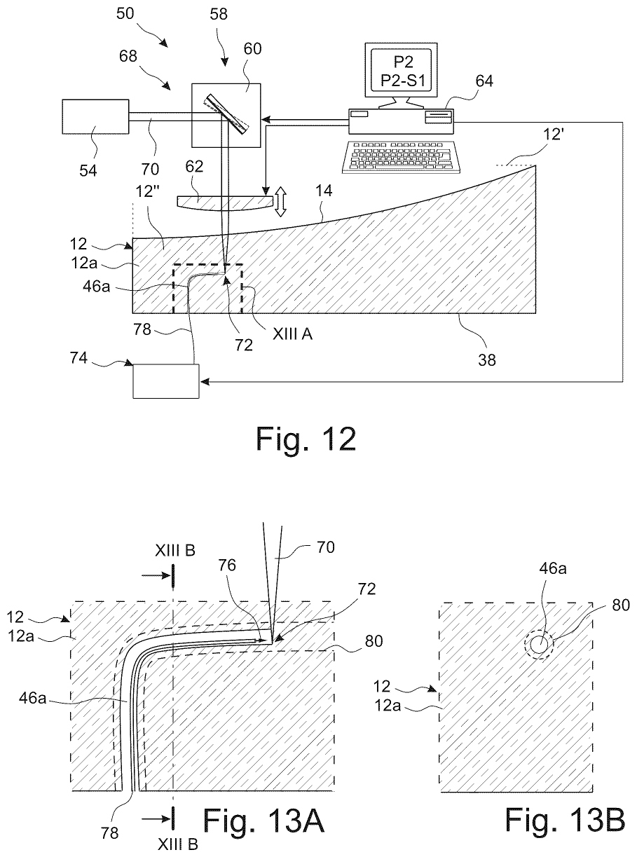

FIGS. 12 to 17B illustrate a second process route P2, with which the intermediate structures 40 can be incorporated into the substrate 12.

In the case of the exemplary embodiments described below, the intermediate hollow structures 46 respectively extend between two openings of the substrate, which are located at the place of the later openings 36 of the temperature-regulating channels 34.

### 2.1 First Process Route P1 to Intermediate Structures 40

Firstly, FIG. 2 illustrates the substrate 12 with a dashed outer contour line as the raw substrate 12′ and with solid lines as the carrier substrate 12′′, i.e., as the substrate 12 with an already formed carrier surface 14, before the reflective coating 16 is applied.

In addition, only the substrate 12 is denoted in the enlargements of details. The outer contour of the raw substrate 12′ is from now on only partially indicated at the edge, if necessary. Also in the raw substrate 12′ the course of the later carrier surface 14 is already fixed, and this then notional carrier surface 14 serves as a reference surface to define the course of the temperature-regulating hollow structures 22 in the substrate 12.

FIG. 2 shows a modification-processing system 48 of a superordinate processing device denoted by 50. With the modification-processing system 48, in a first process step P1-S1 of the first process route P1 material structures 52 of modified substrate material 44 can be incorporated into the substrate 12. There are two alternatives, and material structures 52 of a first kind or material structures 52 of a second kind, marked with 52-I and 52-II, respectively, can be created.

The modification-processing system 48 comprises a light source 54 that generates a modification light beam 56. The light source 54 is preferably a powerful laser that generates short or ultrashort pulses. These may be pulses in the femto-, pico-or nanoseconds range.

The modification light beam 56 can be directed onto different locations of the substrate 12 via a focusing device 58, which comprises a scanning device 60 and a focusing lens element 62. The relative arrangement between the substrate 12 and the modification-processing system 48 may also be changed with the aid of a positioning table (not shown) in such a way that the processing light beam 56 can be directed onto any location of the substrate 12 after passing through the focusing lens element 62. The scanning device 60, the focusing lens element 62 and a positioning table—optionally present—are in this case controlled by a control device 64 in such a way that the processing light beam 56 is successively focused on all of the modification locations 66 of the substrate 12 at which temperature-regulating channels 34 are intended to be produced. Alternatively, the relative arrangement between the substrate 12 and the modification-processing system 48 can be changed by positioning the modification-processing system 50. In the case of small substrates 12 it is possible to dispense with positioning operations, provided that the scanning device 60 covers a sufficiently large area.

At the focal points created by the focusing lens element 62, the intensity of the modification light beam 56 is so high that the material of the substrate 12 is modified there in a targeted manner, in particular by absorption of the high-energy modification light beam 56, wherein in this case there is to a great extent no material loss. This modification can, as it were, be understood as targeted damage to the substrate material 12a, which weakens the material and leads to the increased susceptibility to a chemically active treatment medium. In the present case, the modification leads to an increased susceptibility to etching. In this case, the area in which the modification light beam 56 modifies the substrate material 12a defines a respective modification location 66, which naturally moves along with the focal point of the modification light beam 56.

The locations of the focal points, and consequently the modification locations 66, determine where and with which geometry and which cross sections a temperature-regulating channel 34 is later produced in the substrate 12. In order to create a temperature-regulating channel 34 with a sufficiently large cross section, at a certain axial position the processing light beam 56 travels over the entire cross section in the radial direction according to a predetermined pattern. This process is then repeated at respectively adjacent axial positions until the material structure 52 of the modified substrate material 44 has the desired axial dimension.

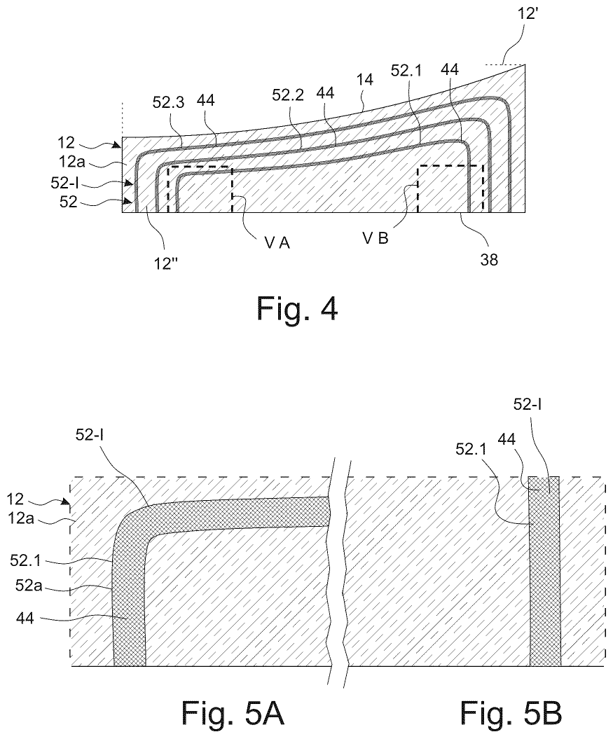

FIGS. 2, 3A and 3B first show here how material structures 52 of the first kind 52-I are incorporated, and these are shown in FIGS. 4, 5A and 5B after their completion. Regardless of whether they are of the first or second kind, as a result the material structures 52 reflect the course and in the course direction the cross sections of the later temperature-regulating channels 34 in the substrate 12, and correspondingly in FIG. 4 bear the reference signs 52.1, 52.2 and 52.3.

In FIGS. 2, 3A and 3B, a portion 52a of a material structure 52 of the first kind 52-I, which has already been incorporated into the substrate 12 and follows the course of the later temperature-regulating channel 34.1, can be seen.

FIG. 3B illustrates on the basis of the cross section of the portion 52a that, in the case of the later material structure 52 of the first kind 52-I, modified substrate material 44 without hollow structures is intended to be present in the cross section, and is present, i.e., that in the case of these material structures 52 of the first kind 52-I the modified substrate material 44 is created in a cross-sectionally filling manner. This does not exclude the possibility that the modified substrate material 44 may be, for example, porous or the like.

As a result, the substrate 12 shown in FIG. 4, in which the material structures 52 of modified substrate material 44 are incorporated, is thus obtained with the aid of the modification-processing system 58. FIGS. 5A and 5B illustrate in this respect, once again on the basis of the details V A and V B according to FIG. 4 with the material structure 52.1, the continuous course of the material structures 52 of the first kind 52-I through the substrate 12.

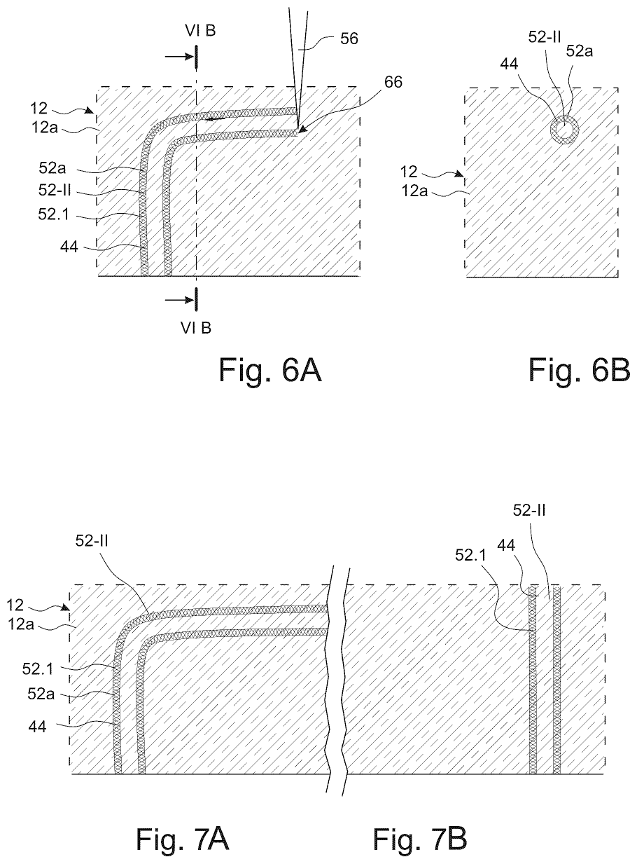

FIGS. 6A and 6B show alternatively how material structures 52 of the second kind 52-II are incorporated into the substrate 12, to be precise on the basis of the example of the material structure 52.1, which follows the course of the later temperature-regulating channel 34.1. FIGS. 6A and 6B show here again a portion 52a of the material structure 52 that has already been incorporated into the substrate 12. As can be seen in FIG. 6B on the basis of the cross section of this portion 52a, in the case of material structures 52 of the second kind 52-II modified substrate material 44 is created in such a way that a core area of substrate material 12a which is, at least in some areas, bounded by modified substrate material 44 remains.

In the case of the exemplary embodiment shown here, the material structure 52 of the second kind 52-II is annular in cross section. FIG. 7 shows its completion on the basis of the material structure 52.1 and the same details that can be seen in FIGS. 5A and 5B.

From now on, reference is to a great extent only made to the material structures 52 generally, and is only made to the first kind 52-I or second kind 52-II in individual cases, if there are differences.

In a second process step P1-S2 of the first process route P1, the above-mentioned intermediate hollow structures 46 are then incorporated into the material structures 52 of modified substrate material 44 in such a way that overall the intermediate structures 40 are produced.

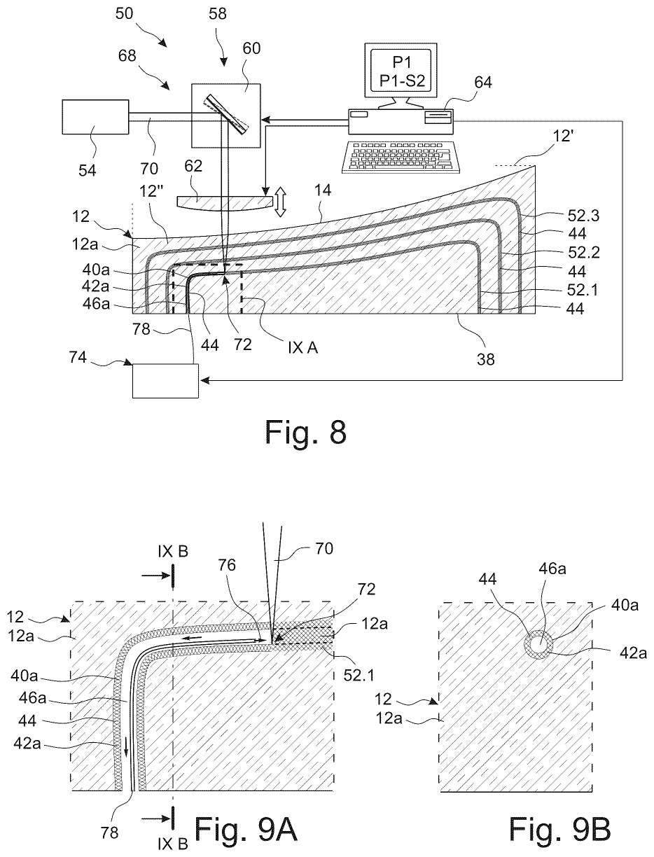

For this purpose, the processing device 50 comprises an ablation-processing system 68 shown in FIG. 8, which to a great extent comprises the same components as the modification-processing system 48, which correspondingly also bear the same reference signs. In principle, what has been said about these components applies correspondingly by analogy.

As a difference from the modification-processing system 48, the light source 54 of the ablation-processing system 68 generates an ablation light beam 70, wherein the light source is also preferably a powerful laser which generates ultrashort pulses.

In the case of the ablation light beam 70, the intensity at the focal points created with the focusing lens element 62 is so high that ablation locations 72 are defined there and the material present is removed. The locations of the focal points, and consequently the ablation locations 72, determine where and with which geometry and which cross sections an intermediate hollow structure 46 is produced in the modified substrate material 44.

In FIGS. 8, 9A and 9B, a portion 46a of an intermediate hollow structure 46 already incorporated in the material structure 52.1 and a portion 40a of an intermediate structure 40 already incorporated in the substrate 12 can be seen, respectively following the course of the material structure 52.1, and consequently the course of the later temperature-regulating channel 34.1. Correspondingly, a portion 42a of the intermediate layer 42 produced is also formed.

The cross sections of the intermediate hollow structures 46 along the course of the material structures 52 are smaller than their respective cross sections, so that as a result the intermediate structures 40 in which each intermediate hollow structure 46 is bounded by an intermediate layer 42 of modified substrate material 44 are produced. In the present case, the intermediate hollow structures 46 are intermediate hollow channels which are bounded by a casing of modified substrate material 44. FIG. 7 illustrates this on the basis of the cross section of the portions 40a/42a/46a, which however also reflects the cross section of a completed intermediate structure 40.

If material structures 52 of the first kind 52-I are present, modified substrate material 44 is removed at the ablation locations 72. If material structures 52 of the second kind 52-II are present, substrate material 12a of the substrate 12 is removed at the ablation locations 72. In this case, the core area outlined by dashed lines in FIG. 9A to the right of the processing light beam 70 still consists of substrate material 12a.

The ablation-processing system 68 also comprises a flushing device denoted as a whole by 74, which is also controlled by the control device 64. The flushing device 74 applies a flushing fluid 76 to the ablation locations 72 while the modified substrate material 44 is being removed, whereby the removed material is flushed away by the flushing fluid 76. Provided for this purpose is a flushing line 78, which has been inserted into the portion 40a/46a and is fed with the flushing fluid 76 via a pump not shown specifically. The discharge end of the flushing line 78 can be made to follow the ablation locations 72 by a line conveyor also not shown separately, which pushes the flushing line 78 along according to the formation of the portion 40a/46a. The removed material is carried along by the flushing fluid 76 and flows off via the already formed portion 40a/46a, which is indicated in FIG. 9A by corresponding arrows.

As a result, the substrate 12 shown in FIGS. 10, 11A and 11B is obtained in this way from the material structures 52—both of the first kind 52-I and of the second kind 52-II—with the aid of the ablation-processing system 68 as an intermediate substrate in which the intermediate structures 40 are incorporated. FIGS. 11A and 11B illustrate in this respect, once again on the basis of the details XI A and XI B according to FIG. 10, the continuous course of the intermediate structures 40 through the substrate 12, which in a way corresponding to the later temperature-regulating channels 34 are additionally denoted by 40.1, 40.2 and 40.3.

In summary, generally speaking, in the case of this first process route P1 in a first process step P1-S1 material structures 52 which comprise modified substrate material 44 are created in the substrate material 12a of the substrate 12 and in a second process step P1-S2 material is removed in such a way that intermediate hollow structures 46 is created and modified substrate material 44 is left standing for the intermediate layer 42, so that the intermediate structures 40 are produced. In the second process step P1-S2, in the case of material structures 52 of the first kind 52-I modified substrate material 44 or in the case of material structures 52 of the second kind 52-II the substrate material 12a of the core area is removed in such a way that the intermediate hollow structure 46 is created and the intermediate layer 42 is formed by modified substrate material 44 of the material structure 52 that remains.

### 2.2 Second Process Route P2 to Intermediate Structures 40

In the case of an alternative second process route P2, on the other hand, in a first process step P2-S1 the intermediate hollow structures 46 are created by the substrate material 12a of the substrate 12 being removed correspondingly, and in a second process step P2-S2 the intermediate layer 42 of modified substrate material 44 is created, so that the intermediate structures 40 are produced.

FIG. 12 illustrates that the ablation-processing system 68 is used for the first process step P2-S1 of the second process route P2; identical components again bear the same reference signs.

In the case of the ablation light beam 70, the intensity at the focal points created with the focusing lens element 62 is so high that the substrate material 12a of the substrate 12 is removed at the ablation locations 72. Here, too, the locations of the focal points, and consequently the ablation locations 72, determine where and with which geometry and which cross sections an intermediate hollow structure 46 is produced, though then in the substrate material 12a of the substrate 12.

In FIGS. 13A and 13B, the course, the geometry and the cross sections of the temperature-regulating hollow structures 22, and specifically of the temperature-regulating channel 34.1, which are intended to be present in the finished mirror 10 are shown by dashed lines 80. As can be seen there, the cross sections of the intermediate hollow structures 46 along the planned course 80 of the temperature-regulating channels 34 are smaller than their respective cross sections.

In FIGS. 12, 13A and 13B, a portion of an intermediate hollow structure 46 already incorporated in the substrate material 12a can be seen, wherein the portion again bears the reference sign 46a and follows the course 80 of the later temperature-regulating channel 34.1.

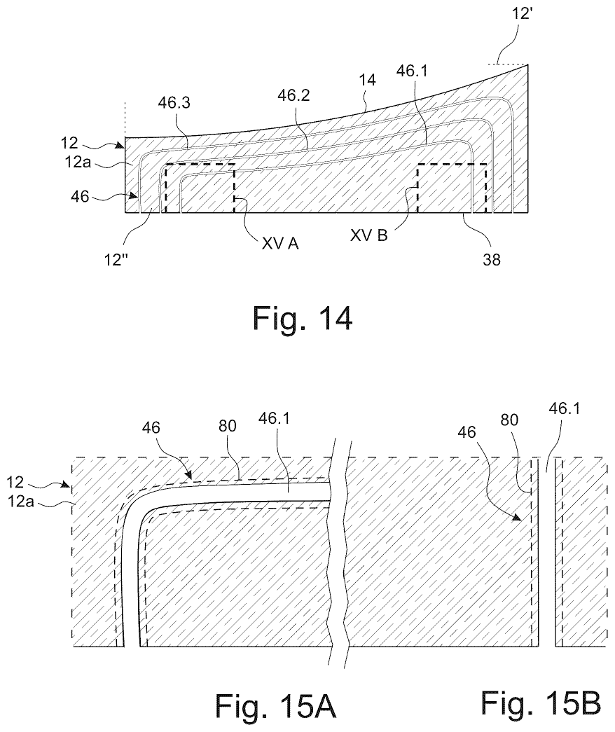

FIGS. 14, 15A and 15B illustrate the result of the first step P2-S1 of the second process route P2, in which the intermediate hollow structures 46 are incorporated in the substrate 12. The intermediate hollow structures 46 reflect the course and in the course direction the cross sections of the later temperature-regulating channels 34 in the substrate 12 and correspondingly in FIG. 14 bear the reference signs 46.1, 46.2 and 46.3.

In the second process step P2-S2 of the second process route P2, the intermediate structures 40 are then created by creating the intermediate layers 42 in the substrate material 12a, which surrounds the intermediate hollow structures 46, so that overall the intermediate structures 40 are produced.

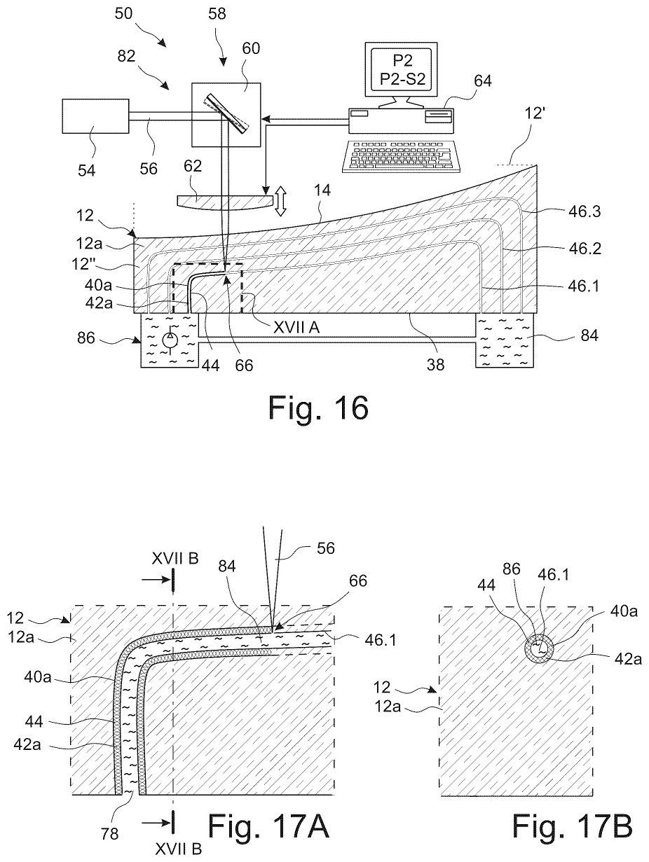

As FIG. 16 shows, used for this purpose is a modified modification-processing system 82, which to a great extent corresponds to the modification-processing system 48 according to FIG. 2 and in which identical components bear the same reference symbols.

Shown in FIGS. 16, 17A and 17B is a portion 42a of an intermediate layer 42 of the modified substrate material 44 already incorporated in the material substrate 12a, whereby a portion 40a of the associated intermediate structure 40 which predetermines the later temperature-regulating channel 34.1, and is accordingly denoted by 40.1, is formed correspondingly.

The lateral surfaces of the intermediate hollow structures 46 produced with the ablation-processing system 68 have a surface roughness with roughnesses that may be greater than 1 μm. Therefore, at these lateral surfaces the modification light beam 56 is scattered, which has an adverse effect on the result in the formation of the intermediate layers 42. In particular, in the worst case, areas in the substrate material 12a that are located on the side of the intermediate hollow structures 46 present that is remote from the focusing lens element 62 can no longer be reached by the modification light beam 56.

This scattering effect can be prevented or sufficiently reduced by an auxiliary fluid 84. The auxiliary fluid 84 is in this case preferably transparent to the modification light beam 56 and more preferably has the same or at least a similar refractive index n as the substrate material 12a of the substrate 12. Preferably, in this case the refractive index nF of the auxiliary fluid 84 at the wavelength of the modification light beam 56 matches the refractive index nM of the substrate material 12a at the same wavelength with a tolerance of less than 20%, preferably with a tolerance of less than 10%, more preferably with a tolerance of less than 5% and particularly preferably with a tolerance of less than 1% relative to the refractive index nM of the substrate material 12a. For example, glycerin and water are suitable as the auxiliary fluid 84.

For this purpose, the modification-processing system 82 additionally comprises a fluid device 86, with which the already formed intermediate hollow structures 46 can be filled with the auxiliary fluid 84. The fluid device 86 is in this case preferably designed in such a way that the auxiliary fluid 84 can be held in the hollow structures as a standing volume of fluid in order to avoid undesirable effects due to turbulence of the auxiliary fluid 84. The pump shown in the case of the fluid device 86 is then only used for filling or emptying the hollow structures, but not for circulating the auxiliary fluid 84.

Depending on the refractive index nF of the auxiliary fluid 84, there is optionally a shift of the focal points, and consequently a shift of the modification locations 66 relative to the focal points or the modification locations that are reached by the modification light beam 56 without the auxiliary fluid 84. This is relevant in particular for those modification locations 66 that are intended to be reached on the side of an intermediate hollow structure 40 already present that is remote from the focusing lens element 62, for which purpose the light must pass through the intermediate hollow structure 40.

This shifting effect on the focal points of the modification light beam 56 is taken into account by the control device 64, so that the modified substrate material 44 is created in the desired areas.

As a result, the intermediate substrate 12 shown in FIGS. 8, 9A and 9B in which the intermediate structures 40 are incorporated is obtained in this way with the aid of the modification-processing system 82.

In summary, in the case of this second process route P2 in the first process step P2-S1 intermediate hollow structures 46 are incorporated into the substrate material 12a of the substrate 12 and in the second process step P2-S2 the intermediate layers 42 of modified substrate material 44 are incorporated into the substate material 12a of the substrate 12 in such a way that the intermediate structures 40 are produced.

### 2.3 Application of Process Routes P1 and P2

The two process routes P1 and P2 described above may also both be applied to the same substrate 12. Depending on the respective geometry and the respective course of different temperature-regulating hollow structures 22, one or the other process route P1 or P2 may be more advantageous in application for different temperature-regulating hollow structures 22. The different alternatives of process routes P1 or P2 may also be applied independently of each other for one and the same substrate 12.

### 2.4 Completing the Temperature-regulating Channels

As mentioned above, the intermediate layers 42 of modified substrate material 44 are then removed by a chemically active treatment medium.

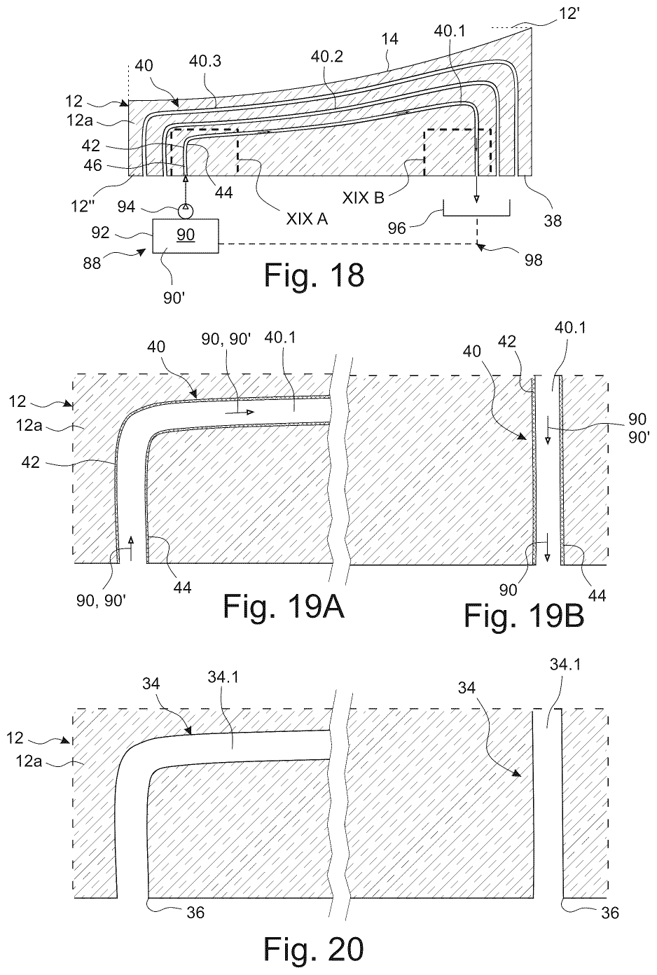

This is illustrated by FIG. 18, in which the intermediate substrate 12 according to FIGS. 10, 11A and 11B can be seen. In the etching step, a treatment device 88 is used to introduce into the intermediate hollow structures 46 of the intermediate structures 40 a chemically active treatment medium 90, by which their intermediate layer 42 of the modified substrate material 44 is removed.

In this case, the treatment medium 90 preferably flows through the intermediate hollow structure 46 continuously over time. In the case of a modification, the treatment medium 90 may also only flow through the intermediate hollow structure 46 at certain times, and over defined time periods be left standing in the intermediate hollow structure 40. The respective intermediate layer 42 and intermediate hollow structure 46 are only denoted in the case of the intermediate structure 40.1.

In the case of the present exemplary embodiment, the chemically active treatment medium 90 is an etching medium 90′ and the intermediate layer 42 of the modified substrate material 44 is removed by an etching process. The treatment device 88 is in this case an etching device. Alternatively, the treatment medium 90 may also be an oxidizing agent or a reducing agent, which also includes that the treatment medium 90 contains an oxidizing agent or a reducing agent.

Alkalis and acids come into consideration as etching agents. In the case of alkalis, they are in particular strong alkalis, such as, for example, potassium hydroxide KOH. Strong acids may also be used, though, in the case of acids, hydrofluoric acid HF, which defines a weak but highly reactive acid, is used in particular. The concentration of the alkalis or acids in the etching medium 90′ is in this case adapted to the required etching effect.

Alternatively, an ammonium fluoride buffer NH4F/H2O/HF may be used, or for dry etching CF4.

The treatment device 88 comprises a reservoir 92 filled with the treatment medium 90, here the etching medium 90′, with a pump 94, which can be connected to an open end of the intermediate structure 40 to be flowed through; in FIG. 18 this is shown in the case of the intermediate structure 40.1.

The other open end of the intermediate structure 40 to be flowed through is connected to a collecting container 96 of the treatment device 88. Optionally, the etching medium 90′ may also be passed through the intermediate structure 40 in several cycles by a circulatory system 98 schematically indicated by a dashed line. This also applies generally to a treatment medium 90.

FIGS. 19A, 19B, 20A and 20B illustrate on the basis of the details XIX A and XIX B in FIG. 18 how the intermediate layer 42 in the case of the intermediate structure 40.1 in FIGS. 19A and 19B has become thinner compared to the initial situation according to FIGS. 11A and 11B, and is further removed or etched away by the treatment medium 90 or the etching medium 90′ until the temperature-regulating channel 34.1 shown in FIGS. 20A and 20B is completed.

Such treatments or etching treatments of the intermediate layers 42 are carried out in the case of all of the intermediate structures 40 present until as a result the substrate 12 of the mirror 10 with the temperature-regulating hollow structures 22 according to FIG. 1 is obtained, in which however the coating 16 has not yet been applied to the carrier surface 14.

Because the etching medium 90′ flows through already existing intermediate hollow structures 46 that are externally accessible at both ends, a uniform attack or etching attack on the modified substrate material 44 in the intermediate layers 42 is ensured, without there being congestion effects in dead volumes. The treatment medium 90 or the etching medium 90′ in this case behaves like a laminar flow; no dead zones are produced.

In addition, for the sake of simplicity, reference is made to the etching step with the etching medium 90′ as the treatment step. What has been said in this respect applies correspondingly by analogy to a treatment step with an alternative chemically active treatment medium 90.

### 2.5 Corrections of Irregularities

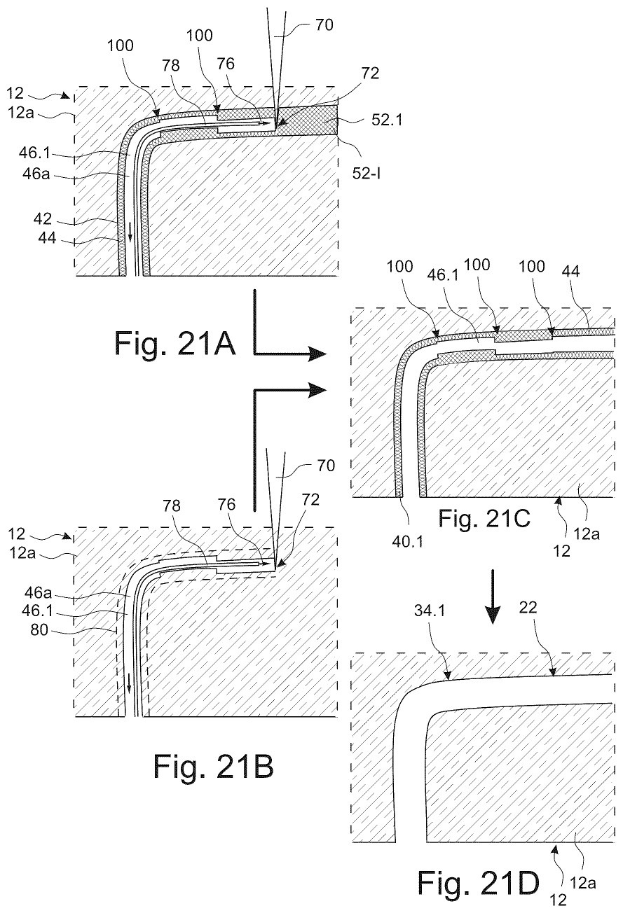

FIGS. 21A-D show by way of example the possibility of compensating for irregularities by the two process routes P1 and P2 in combination with the subsequent etching step, which can occur in the case of the intermediate hollow structures 46 if they are incorporated into the material structures 52 of modified substrate material 44 or directly into the substrate material 12a.

FIGS. 21A and 21B show here the detail IX A from FIG. 8 and the detail XIII A from FIG. 12 respectively, and in each case illustrate how on the one hand modified substrate material 44 of the material structure 52.1 of the first kind 52-I in the case of the first process route P1 and on the other hand the substrate material 12a in the case of the second process route P2 is removed by the ablation light beam 70, wherein however irregularities in the form of offset points 100 have occurred in each case in the intermediate hollow structure 46.1. Such irregularities may be produced in, for example, the event of interruptions in the removal process or also in the event of fluctuations in the microstructure of the material structures 52 or of the substrate 12.

As a result, the intermediate substrate 12 according to FIG. 10 then has such offset points 100 in the intermediate structures 40 formed, which FIG. 21C shows on the basis of the intermediate structure 40.1.

As long as, in the radial direction, such offset points 100 are still within the outer boundary of the temperature-regulating channel 34 to be created, the offset points 100 can be compensated by the etching step.

As FIG. 21A shows, this is the case with the first process route P1 when in the first process step P1-S1 there the material structure 52.1 has been incorporated with a sufficiently large cross section that even an offset point 100 radially outside still remains surrounded by modified substrate material 44.

FIG. 21B shows that this is the case with the second process route P2 when in the first process step P2-S1 there the intermediate hollow structure 46.1 with the offset points 100 is still created within the planned geometry 80 of the temperature-regulating channel 34.1. In the second process step P2-S2 of the second process route P2, the intermediate layer 42 is then created with a uniform cross section in itself, so that even an offset point 100 radially outside is surrounded by modified substrate material 44.

In the case of both process routes P1 and P2, an intermediate structure 40 of which the intermediate hollow structure 46 has corresponding offset points 100 is produced; this is shown once again by FIG. 19B.

When the etching step is carried out, the etching selectivity of the etching medium 90′ is sufficient to etch away thicker-wall and thinner-wall areas of the intermediate layer 42 without the surrounding substrate material 12a being excessively affected. When the thinner-wall areas of the intermediate layer 42 have been etched away, it is true that the etching medium 90′ there can already flow over the substrate material 12a and attack it before the thicker-wall areas have been removed. However, the necessary time period in which the intermediate layer 42 still present is removed by the etching medium 90′ is not sufficient to damage intolerably the substrate material 12 already flowed over.

As a result, even when there are offset points 100 present in the lateral surface of the intermediate hollow structures 46, associated temperature-regulating hollow structures 22 with satisfactory functionality are created by the etching step, which FIG. 21D illustrates.

### 3. Substrate Obtained

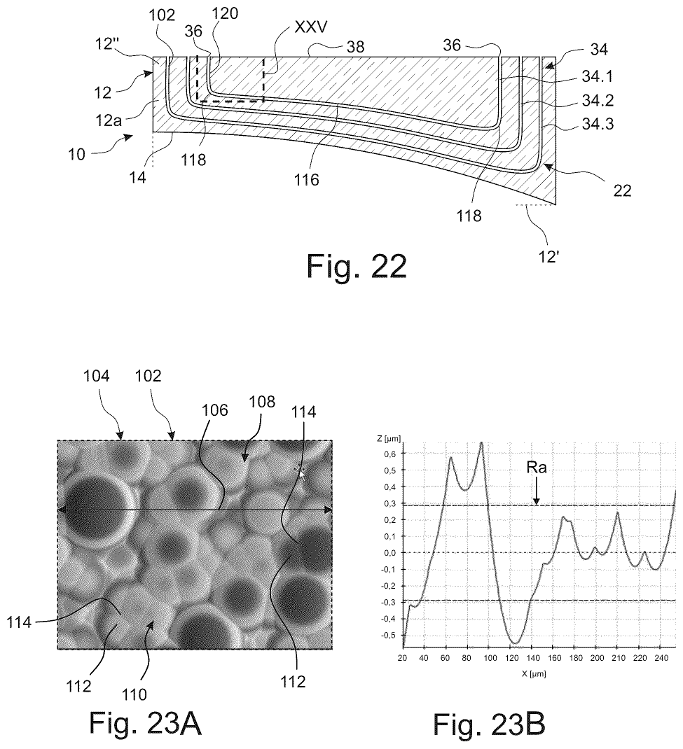

FIG. 22 then shows once again the substrate 12 in the stage of the carrier substrate 12″ with temperature-regulating hollow structures 22 which were obtained by the method explained above and are again represented by way of example by three temperature-regulating channels 34.1, 34.2 and 34.3. The temperature-regulating hollow structures 22 respectively define an inner lateral surface 102, wherein for the sake of clarity only one inner lateral surface 102 of these is provided with a reference sign.

There follows an explanation of properties of the temperature-regulating hollow structures 22 or the temperature-regulating channels 34 and the substrate 12 as such which are possible or result when the methods described above are applied, wherein optionally properties that have already been described are also taken up again and/or supplemented.

### 3.1 Temperature-regulating Hollow Structures/temperature-regulating Channels

Application of the first or second process route P1 and P2 for forming the temperature-regulating hollow structures 22 has the effect of obtaining substrates 12 with temperature-regulating hollow structures 22 of which the inner lateral surface 102 has, at least in some areas, an extremely high quality with an average roughness Ra of between 10.0 μm and 5.0μm, which in this case may in particular lie between 10.0 μm and 6.5μm, between 10.0 μm and 8.0μm, between 8.5 μm and 5.0μm, between 7.0 μm and 5.0 μm or between 8.5 μm and 6.5μm, or the inner lateral surface 102 of which has, at least in some areas, an extremely high quality with an average roughness Ra of 5.0 μm and less, which in this case may in particular lie between 5.0 μm and 0.1 μm, between 4.5 μm and 0.125 μm, between 4.0 μm and 0.15 μm, between 3.5 μm and 0.175μm or between 3.0 μm and 0.2μm. In practice, it has been possible in particular to achieve particularly good average roughnesses Ra of between 0.1 μm and 0.5μm, between 0.15 μm and 0.45μm, between 0.2 μm and 0.4 μm and between 0.25 μm and 0.35 μm. In principle, however, the mentioned average roughnesses Ra of between 10.0 μm and 5.0 μm are also a good result.

FIG. 23A shows a topography image of a surface area 104 of the inner lateral surface 102 of such a temperature-regulating hollow structure 22 and FIG. 23B shows a section along the section line denoted in FIG. 23A by 106, which illustrates an average roughness Ra achieved there of about 0.28 μm. The surface area 104 has an extent of 254 μm×190 μm.

The average roughnesses Ra are determined and specified in accordance with DIN EN ISO 25178 (as of 04/2023). The measurement was performed via a white light interferometer with 50× magnification, as is known per se.

FIG. 23A illustrates that applying the first process route P1 or the second process route P1 has the effect of obtaining, at least in surface areas of the inner lateral surface 102 of the temperature-regulating hollow structures 22, a surface topography 108 of which the geometric shape results from an overlaying of sunken structures 110 which extend into the substrate material 12a.

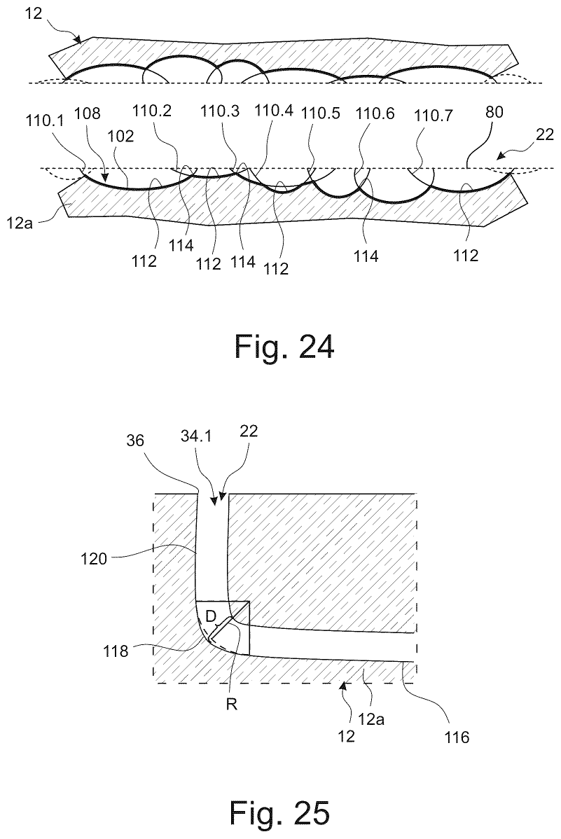

This is additionally illustrated schematically in FIG. 24 on the basis of a longitudinal section of a temperature-regulating hollow structure 22, clearly exaggerated in terms of its proportions and without reference to the image according to FIG. 23A, wherein only the transition at the bottom of FIG. 24 between the temperature-regulating hollow structure 22 and the substrate material 12a is discussed below. By way of example, seven sunken structures 110.1, 110.2, 110.3, 110.4, 110.5, 110.6 and 110.7 extending into the substrate material 12a can be seen there with solid lines.

The planned course 80 of the temperature-regulating hollow structure 22, explained above in relation to FIGS. 13A and 13B and shown in FIG. 24 again with a dashed line, describes here a reference lateral surface from which the sunken structures 108 extend into the substrate material 12a. The overlaying of these sunken structures 110 results then in the surface topography 108, the course of which can be seen with a thicker solid line in the section shown in FIG. 24.

As a result, the surface topography 108 defines mutually adjoining sunken areas 112, between which peripheral regions 114 run. In FIG. 23A, only a few such sunken areas and peripheral regions are provided with reference signs.

By way of illustration, these peripheral regions 114 form a kind of mountain ridge between two adjacent valleys in the form of two mutually adjoining sunken areas 112. These peripheral regions 114 may in particular be linear.

The sunken structures 110 may in particular be segments of in themselves point-symmetrical or at least axis-symmetrical bodies, such as, for example segments, of a sphere, segments of an ellipsoid or paraboloids. The resulting sunken areas 112 may for their part be axis-symmetrical and, for example, follow a portion of the outer lateral surface of segments of a sphere, segments of an ellipsoid or paraboloids. In this case, their peripheral regions 114 are also axis-symmetrical. However, sunken areas 112 that are not axis-symmetrical, with peripheral regions 114 that are not axis-symmetrical, may also be produced and present, which can be seen in FIG. 23A on the basis of the two sunken areas respectively denoted there by 112 and their peripheral regions denoted by 114. The final geometry and dimension of a sunken area 112 surrounded by a circumferential peripheral region 114 depends on the geometries and dimensions of the sunken structures 110, which are understood as the basis for the formation of the sunken area 112. For the sake of completeness, it should be noted that the sunken structures 110 are distributed over the surface area of the lateral surface 102, but FIG. 25 can of course only show the section shown and no sunken structures 110 and resulting sunken areas 112 in front of and behind the plane of the paper.

A temperature-regulating channel 34 may have diameters of between 0.5 mm and 20 mm, with diameters of between 1 mm and 5 mm preferably being formed.

The length of a temperature-regulating channel 34 depends primarily on the dimension of the substrate 12 and in practice is at least 10 cm, but may also be at least 15 cm or at least 20 cm.

A temperature-regulating channel 34 may be curved or at least have curved portions. As can be seen in FIG. 22, the temperature-regulating channels 34 in a middle portion 116 thereof follow the curvature of the carrier surface 14, this middle portion 116, which is consequently already a curved portion, extending between two comparatively strongly curved portions 118. In FIG. 22, the middle portion 116 and the strongly curved portions 118 are only denoted by a reference sign in the case of the temperature-regulating channel 34.1. The middle portion 116 denoted there opens in FIG. 22 to the left into the strongly curved portion 118 there, which for its part goes over into a straight portion 120, which then ends at the opening 36 of the temperature-regulating channel 34.1. FIG. 25 shows the detail XXV of FIG. 22 on an enlarged scale.

A strong curvature should be understood as meaning angles of curvature of between 60° and 120°, in particular between 80° and 100°, preferably of about 90°. Preferably, a portion 116 of the temperature-regulating channel 34 extends between two strongly curved portions 118 with an angle of curvature of about 90°, as shown in the case of the present exemplary embodiment.

The curvature of a strongly curved portion 118 in this case generally follows an arc. With a 90° curvature, for example, there are not two strictly perpendicular portions of the channel.

An outer radius of curvature R and the diameter D of a strongly curved portion, here the strongly curved portion 118, also illustrated in FIG. 25, define a ratio R/D. Preferably, such a ratio R/D lies between 2 and 6, more preferably between 2.5 and 5, and in particular preferably between 2.5 and 3.5. These ratios R/D are not reflected by FIG. 25 or the other figures; to allow this to be seen better, the temperature-regulating channel 34.1 is shown schematically with a proportionally larger diameter.

Relative to the carrier surface 14 of the substrate 12, a temperature-regulating channel 34 runs in particular at a distance of 1.0 mm to 50.0 mm, of 1.0 mm to 20.0 mm, of 1.0 mm to 10.0 mm or of 1.0 mm to 5.0 mm. The distance is in this case preferably determined relative to a normal to the carrier surface 14. In this case, the distance between the temperature-regulating channel 34 and the carrier surface 14 along its course may be different.

### 3.2 Substrate

The methods explained above are used to obtain a substrate 12 provided with temperature-regulating hollow structures 22 and with a carrier surface 14 of which the surface figure has a significant stability over time. With a lifetime of the substrate 12 of up to 10 years, at least up to five years and at least up to two years, the surface figure of the carrier surface 14 changes by less than 100 pm, in particular by less than 50 pm and further in particular by less than 25 pm.

This stability of the surface figure is also retained in the case of a mirror 10, which comprises a substrate 12 produced via the methods explained above and is provided with the coating 16. Consequently, a mirror 10 is obtained such that, with a lifetime of the mirror 10 of up to 10 years, at least up to five years and at least up to two years, its surface figure changes by less than 100 pm, in particular by less than 50 pm and further in particular by less than 25 pm.

The high stability of the surface figure of the carrier surface 14 of the substrate 12 and the surface figure of the mirror 10 produced from it is achieved in that the modified substrate material 44 is precisely and purposefully removed, so that a substrate which is particularly homogeneous in itself in terms of its microstructure is obtained or restored after the microstructure no longer has this microstructure homogeneity when the modified substrate material 44 is still present.

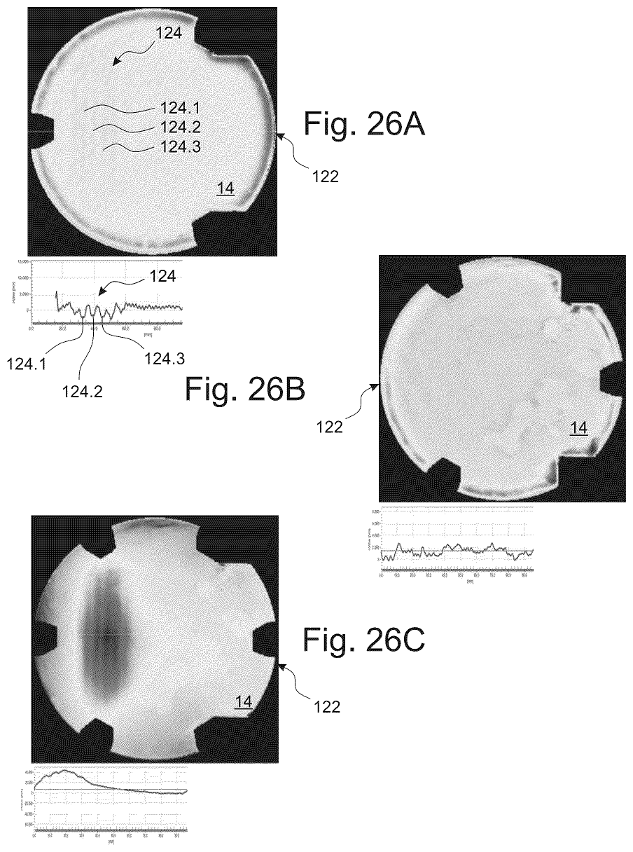

This is reflected by the presentations in FIGS. 26A, 26B and 26C of the results of measurements of the surface figure of the carrier surface 14 of a substrate 122 processed in practice for a mirror before and after the etching process, with a surface-image representation of the carrier surface 14 being shown in each case at the top and a deviation profile along a measuring section shown thereunder.

The measurements were carried out using an interferometric measurement system which is based on a Fizeau interferometer and provides a repeatability of 10 pm RMS and a pixel size of typically 0.12 mm×0.12 mm.

FIG. 26A shows the surface figure of the carrier surface 14 in the case of the substrate 122 before the etching process with which the modified substrate material 44 is removed, and consequently reflects the configuration of the substrate 12 with the intermediate structures 40 according to FIG. 10, in which the modified substrate material 44 is still present. Depressions 124 in the carrier surface 14 are shown, of which three depressions are denoted by 124.1, 124.2 and 124.3 in the surface-image representation and the deviation profile. These depressions 124 are present where, below the carrier surface 14, the intermediate structures 40 are incorporated in the substrate material 12a and the modified substrate material 44 is present. As can be seen in FIG. 26A, the depressions 124 follow the respective course of the intermediate structures 40, which in this case can be seen as straight-line channels. The measuring section of the respective deviation profile of FIG. 26A, B and C runs transversely to the channels.

For comparison purposes, the substrate 122 is not provided with intermediate structures 40 under the full carrier surface 14; the area to the right of the depressions 124 is unprocessed.

The depressions 124 are produced due to the microstructure inhomogeneities in the substrate material 12a that have been produced there below the carrier surface 14 by the modified substrate material 44

FIG. 26B shows the surface figure of the carrier surface 14 in the case of the substrate of FIG. 26A after carrying out the etching process with which the modified substrate material 44 is removed, which corresponds to the configuration of the substrate 12 according to FIG. 22. As FIG. 26B shows and becomes clear on the basis of the deviation profile, the depressions 124 have significantly decreased after the removal of the modified substrate material 44, and the carrier surface 14 then has a lower overall figure deviation.

FIG. 26C shows a representation of the differences in the measurements according to FIGS. 26A and 26B and in this context also illustrates the largely unchanged areas of the carrier surface 14 without underlying temperature-regulating hollow structures 22.

In any case, the surface figure measured according to FIG. 26B has the stability over time explained above.

### 4. Semiconductor Technology Apparatus/projection Exposure Apparatus

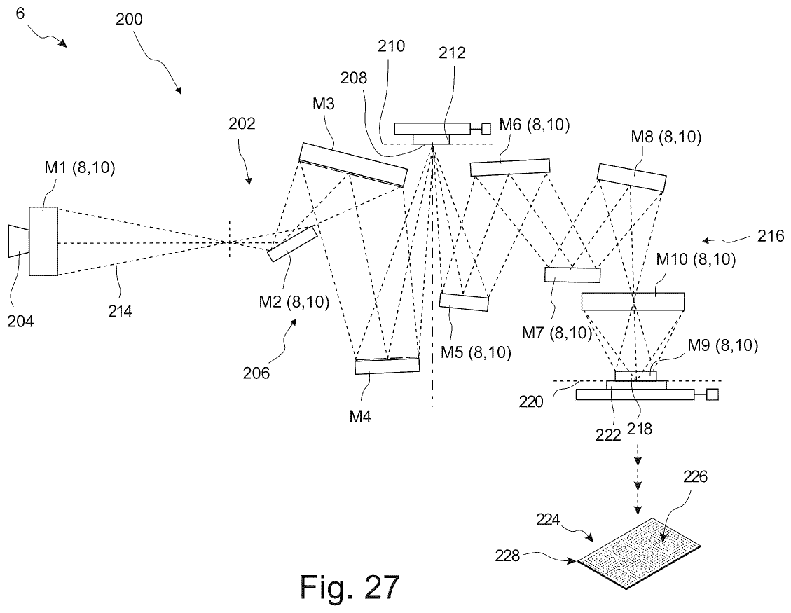

FIG. 27 illustrates once again a semiconductor technology apparatus 6 on the basis of the example of a projection exposure apparatus 200 for EUV semiconductor lithography. Other semiconductor technology apparatuses, such as, for example, a mask inspection apparatus or a wafer inspection apparatus, contain components in part identical or similar to those as explained here on the basis of the example of the EUV projection exposure apparatus 200.

The projection exposure apparatus 200 comprises an illumination system 202 with a radiation source 204 and an illumination optical unit 206 for illuminating an object field 208 in an object plane 210, in which a reflective reticle 212 is arranged. In the exemplary embodiment shown, the radiation source 204 is an EUV radiation source which emits EUV radiation as working radiation 214, in particular in a wavelength range of between 5 nm and 30 nm. The radiation source 204 may be a plasma source, for example an LPP (laser produced plasma) source or a GDPP (gas discharge produced plasma) source. Alternatively, a synchrotron-based radiation source or a free electron laser (FEL) may be used as the radiation source 204.

Moreover, the projection exposure apparatus 200 comprises a projection optical unit 216 for imaging the object field 208 into an image field 218 located in an image plane 220 of the projection optical unit 216. As an example of an object 222, a wafer carrying a light-sensitive layer (referred to as a resist) is arranged in the image plane 220. Components for synchronously moving the reticle 212 and the wafer 222 are merely indicated in FIG. 27 and are not provided with reference signs.

The projection exposure apparatus 200 comprises a plurality of optical elements 8 in the form of mirrors Mn, which are consecutively numbered in accordance with their arrangement in the beam path of the projection exposure apparatus 200. In the present case, a total of 10 mirrors M1 to M10 are present in the beam path.

The mirrors M3 and M4 are formed as facet mirrors containing a multiplicity of individual mirrors. The other mirrors Mn are in each case a mirror 10 with a monolithic mirror substrate 12 and a coating 16 carried thereby, as shown by way of example in FIG. 1. For the sake of simplicity, these mirrors are indicated in FIG. 27 as parallelepipeds. In reality, however, the surfaces of the mirrors 10 that are exposed to the EUV radiation 214 and provided with the coating 16 are not planar, but rather curved, as likewise illustrated by FIG. 1.

The mirrors M1 to M4 in the illumination system 206 are used to illuminate a portion of the reticle 212 with the desired illumination angle distribution. The mirrors M5 to M10 of the projection optical unit 216 image this portion onto the wafer 222 in a reduced size. As a result, the structures contained in the reticle 212 are imaged onto the light-sensitive layer carried by the wafer 222.

With the aid of the optical elements 8, which in the case of the present exemplary embodiment are formed as mirrors 10 for the EUV projection exposure apparatus 200 and the coating of which is designed at least to reflect at least 50% of EUV light impinging with normal or almost normal incidence, the object 222 is irradiated with the working radiation 214.

The semiconductor technology apparatus 6 is part of a production process which can be used to produce a structured electronic component 224, which is schematically shown in FIG. 27 with produced structures 226 as the result of an overall production process comprising even further steps in addition to the process in the semiconductor technology apparatus 6. What is relevant here, however, is that the semiconductor technology apparatus 6 comprises at least one optical element 8 which was produced in one of the ways included by the method variants explained above.

The structured electronic component 224 is in particular a computer chip 228, during the production of which a projection exposure apparatus, here the projection exposure apparatus 200, is used, as was discussed at the beginning.

### 5. Concluding Remarks

All of the methods, steps, sequences, concepts and principles above can be combined with one another, which is also reflected in the combinations of features specified in the claims.

### 6. Method Aspects

Specific method aspects of the disclosed techniques and some resulting advantages are described with reference to the following clauses:

1. A method for incorporating temperature-regulating hollow structures (22) into a substrate (12), in particular into a substrate (12) for an optical element (8), in particular for a mirror (10) for an EUV projection exposure apparatus, with the following steps:
(A) providing a substrate (12) which consists of a substrate material (12a);

(B) creating an intermediate structure (40) which comprises an intermediate layer (42) of modified substrate material (44) and an intermediate hollow structure (46) which is, at least in some areas, bounded by the intermediate layer (42), wherein the modified substrate material (44) has an increased susceptibility to a chemically active treatment medium relative to the substrate material (12a);

(C) introducing into the intermediate hollow structure (46) a chemically active treatment medium (90) by which the intermediate layer (42) of the modified substrate material (44) is removed, thereby producing the temperature-regulating hollow structure 22); characterized in that
the intermediate structure (40) is created in step (B) by
(B.1) successively focusing a modification light beam (56) on modification locations (66), so that the modified substrate material (44) is produced at the modification locations (66); and
(B.2) successively focusing an ablation light beam (70) on ablation locations (72), so that material (44; 12a) is removed at the ablation locations (72).

It has been recognized that, by a combination of a targeted creation of modified material with a targeted removal of material, temperature-regulating hollow structures of high quality and homogeneously roughness-free surface properties can be incorporated into a substrate. While in the case of the known method the modified substrate material is to a great extent produced unpredictably, according to the disclosed techniques the modified substrate material is created in a targeted manner with a modification light beam. This makes it possible, above all, that the cross-sectional course of the temperature-regulating hollow structures can be planned with high precision.

2. The method as specified in clause 1, characterized in that a first process route (P1) or a second process route (P2) is carried out, wherein
in the case of the first process route (P1), step (B.1) is carried out in a first process step (P1-S1) and step (B.2) is carried out in a second process step (P1-S2); and
in the case of the second process route (P2), step (B.2) is carried out in a first process step (P2-S1) and step (B.1) is carried out in a second process step (P2-S2).

Advantageously, the method allows a first process route (P1) or a second process route (P2) to be carried out and the sequence of modification and removal can therefore be performed according to choice.

3. The method as specified in clause 2, characterized in that the first process route (P1) is carried out and
in its first process step (P1-S1) material structures (52) which comprise modified substrate material (44) are created by step (B.1); and
in its second process step (P1-S2) material (44; 12a) is removed by step (B.2) in such a way that the intermediate hollow structure (46) is created and modified substrate material (44) of the material structure (52) is left standing for the intermediate layer (42).

If the first process route (P1) is carried out, in comparison with known methods, in which almost all the substrate material is removed over the cross section of the desired temperature-regulating hollow structure, here the volume is reduced by the portion defined by the modified substrate material left standing. As a result, less time is required for the removal of the material.

4. The method as specified in clause 3, characterized in that in the first process step (P1-S1) of the first process route (P1) step (B.1) is carried out in such a way that material structures (52) of a first kind (52-I) or material structures (52) of a second kind (52-II) are created, wherein
in the case of material structures (52) of the first kind (52-I), the modified substrate material (44) is created in a cross-sectionally filling manner; and
in the case of material structures (52) of the second kind (52-II), modified substrate material (44) is created in such a way that a core area of substrate material (12a) which is, at least in some areas, bounded by modified substrate material (44) remains.

Here, the method again advantageously opens up two alternative procedures.

5. The method as specified in clause 4, characterized in that in the second process step (P1-S2) of the first process route (P1) step (B.2) is carried out in such a way that in the case of material structures (52) of the first kind (52-I) modified substrate material (44) and in the case of material structures (52) of the second kind (52-II) the substrate material (12a) of the core area is removed in such a way that the intermediate hollow structure (46) is created and the intermediate layer (42) is formed by the modified substrate material (44) of the material structure (52) that is left standing.

6. The method as specified in one of clauses 2 to 5, characterized in that the second process route (P2) is carried out and
in its first process step (P2-S1) substrate material (12a) of the substrate (12) is removed by step (B.2) in such a way that the intermediate hollow structure (46) is created; and
in its second process step (P2-S2), the intermediate layer (42) is created from modified material (44) by step (B.1), so that the intermediate structure (40) is produced.

Here too, less material is removed than in the prior art and correspondingly less time is required.

7. The method as specified in clause 6, characterized in that, in the case of the second process step (P2-S2) of the second process route (P2), the intermediate hollow structure (46) is filled with an auxiliary fluid (84), so that it is filled with the auxiliary fluid when step (B.1) is carried out, wherein the auxiliary fluid is preferably held as a standing fluid volume.

8. The method as specified in clause 7, characterized in that it uses an auxiliary fluid (84) of which the refractive index n_{F} at the wavelength of the modification light beam (56) matches the refractive index n_{M} of the substrate material (12a) at the same wavelength with a tolerance of less than 20%, preferably with a tolerance of less than 10%, preferably with a tolerance of less than 5% and particularly preferably with a tolerance of less than 1% relative to the refractive index n_{M} of the substrate material (12a).

9. The method as specified in one of clauses 1 to 8, characterized in that flushing fluid (76) is applied to the ablation locations (72) while step (B.2) is being carried out, whereby material (44; 12a) removed is flushed away.

10. The method as specified in one of clauses 1 to 9, characterized in that in step (C) the chemically active treatment medium (90) is made to flow at least at certain times, preferably continuously over time, through the intermediate hollow structure (40).

This is of particular advantage for the final formation of the temperature-regulating hollow structure

11. The method as specified in one of clauses 1 to 10, characterized in that the chemically active treatment medium (90) is an etching medium (90′), an oxidizing agent or a reducing agent, and in particular is an etching medium (90′) by which in step (C) the intermediate layer (42) of the modified substrate material (44) is removed by an etching process.

12. A method for producing an optical element, in particular for producing a mirror (10) for an EUV projection exposure apparatus, characterized in that temperature-regulating hollow structures (22) are incorporated into the substrate (12) in accordance with the method as specified in one of clauses 1 to 11 and further processing comprises one or more steps of chemical and/or physical processing of at least one surface of the substrate (12) and also creating or applying on the substrate (12) a coating (16) which is designed at least to reflect at least 50% of EUV light impinging with normal or almost normal incidence.

What is claimed is:

1. A substrate for producing a mirror for an EUV projection exposure apparatus, comprising:
at least one temperature-regulating hollow structure comprising a strongly curved portion which has an angle of curvature of between 60° and 120° and an inner lateral surface, wherein:
the inner lateral surface which has, at least in some areas, an average roughness Ra in accordance with DIN EN ISO 25178, as of April 2023, of between 10.0 μm and 5.0μm, or the inner lateral surface which has, at least in some areas, an average roughness Ra of 5.0 μm and less.

2. The substrate of claim 1, wherein the average roughness is between 10.0 μm and 8.0 μm, between 8.5 μm and 5.0 μm, between 7.0 μm and 5.0 μm or between 8.5 μm and 6.5μm.

3. The substrate of claim 1, wherein the average roughness is between 4.5 μm and 0.125μm, between 4.0 μm and 0.15μm, between 3.5 μm and 0.175 μm or between 3.0 μm and 0.2μm.

4. The substrate of claim 1, wherein the angle of curvature is between 80°and 100°.

5. A substrate for producing a mirror for an EUV projection exposure apparatus, comprising at least one temperature-regulating hollow structure that defines an inner lateral surface which has a surface topography of which a geometric shape results from an overlaying, at least in some areas, of sunken structures which extend into a substrate material of the substrate.

6. The substrate of claim 5, wherein at least one of the sunken structures comprises segments that are point-symmetrical or axis-symmetrical bodies.

7. The substrate of claim 5, wherein the surface topography defines mutually adjoining sunken areas, between which peripheral regions run.

8. The substrate of claim 7, wherein at least one of the mutually adjoining sunken areas is an axis-symmetrical sunken area that follows a portion of an outer lateral surface of a segment of a sphere, a segment of an ellipsoid or of a paraboloid.

9. The substrate of claim 5, wherein the at least one temperature-regulating hollow structure is a temperature-regulating channel, which has one or more of the following features:
a) the temperature-regulating channel has a diameter of between 0.5 mm and 20 mm;
b) the temperature-regulating channel has a length of at least 10 cm, at least 15 cm or at least 20 cm;
c) the temperature-regulating channel is curved or has at least one curved portion;
d) the temperature-regulating channel has a portion which follows a curvature of a carrier surface for a coating of the substrate;
e) the temperature-regulating channel has a strongly curved portion which has an angle of curvature of between 60°and 120 and follows an arc;
f) the temperature-regulating channel has a strongly curved portion which has an angle of curvature of between 60° and 120° and follows an arc and defines an outer radius of curvature R and a diameter D, wherein a ratio R/D of the radius of curvature R to the diameter D lies between 2 and 6; or
g) the temperature-regulating channel is at a distance relative to a carrier surface for a coating of the substrate of 1.0 mm to 50.0 mm, of 1.0 mm to 20.0 mm, of 1.0 mm to 10.0 mm or of 1.0 mm to 5.0 mm.

10. The substrate of claim 5, wherein the at least one temperature-regulating hollow structure comprising a strongly curved portion which has an angle of curvature of between 60° and 120° and an inner lateral surface, and
wherein the inner lateral surface which has, at least in some areas, an average roughness Ra in accordance with DIN EN ISO 25178, as of April 2023, of between 10.0 μm and 5.0 μm or the inner lateral surface which has, at least in some areas, an average roughness Ra of 5.0 μm and less.

11. A substrate for producing an optical element for an EUV semiconductor technology apparatus, comprising
temperature-regulating hollow structures, and
a carrier surface for a coating,
wherein the substrate has a lifetime of two or more years during which a surface figure of the carrier surface changes by less than 100 pm.

12. The substrate of claim 11, wherein at least one of the temperature-regulating hollow structures comprises a strongly curved portion which has an angle of curvature of between 60°and 120°and an inner lateral surface, and
wherein the inner lateral surface which has, at least in some areas, an average roughness Ra in accordance with DIN EN ISO 25178, as of April 2023, of between 10.0 μm and 5.0 μm or the inner lateral surface which has, at least in some areas, an average roughness Ra of 5.0 μm and less.

13. An optical element for an EUV semiconductor technology apparatus, comprising a substrate with a lifetime of two years or more years during which a surface figure of the optical element changes by less than 100 pm.

14. The optical element of claim 13, wherein the surface figure of the optical element changes by less than 25 pm.

15. The optical element of claim 13, wherein the optical element is a mirror for an EUV projection exposure apparatus, wherein the substrate has a carrier surface which carries a coating which is designed to reflect at least 50% of EUV light impinging with normal or almost normal incidence.

16. The optical element of claim 15, wherein the carrier surface changes by less than 100 pm in the two or more years.

17. A semiconductor technology apparatus, comprising an optical element as claimed in claim 11.

18. The apparatus of claim 17, wherein the apparatus comprises an EUV projection exposure apparatus and in that the optical element is a mirror as claimed in claim 14.

19. The apparatus of claim 17, wherein the apparatus comprises a mask inspection apparatus.

20. The apparatus of claim 17, wherein the apparatus comprises a wafer inspection apparatus.
